(19) United States
(12) Patent Application Publication
(10) Pub. No.: US 2009/0060702 A1
(43) Pub. Date: Mar. 5, 2009

(54) METHOD FOR TRANSPORTING OBJECT TO BE PROCESSED IN SEMICONDUCTOR MANUFACTURING APPARATUS

(76) Inventors: Hiroyuki Kobayashi, Kodaira (JP); Kenji Maeda, Koganei (JP); Masaru Izawa, Hino (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/035,780

(22) Filed: Feb. 22, 2008

(30) Foreign Application Priority Data
Sep. 5, 2007 (JP) 2007-229996

(51) Int. Cl. H01L 21/673

(52) U.S. Cl. 414/805

(57) ABSTRACT

In a semiconductor manufacturing apparatus including a processing chamber, means for supplying gas to the processing chamber, evacuating means for decompressing the processing chamber, a transport chamber, means for supplying gas to the transport chamber, and evacuating means for decompressing the transport chamber, the pressure in the processing chamber is 10 to 50 Pa, the pressure in the transport chamber is set to positive pressure to the processing chamber, the differential pressure between the processing chamber and the transport chamber is 10 Pa or less, and the flow rate of the gas supplied to the processing chamber is twice or more the flow rate of gas supplied to the transport chamber.

### CLAIM OF PRIORITY

The invention claims priority from Japanese application JP 2007-229996 filed on Sep. 5, 2007, the content of which is hereby incorporated by reference into this application.

### FIELD OF THE INVENTION

This invention relates to a transport method for an object to be processed such as a wafer in a semiconductor manufacturing apparatus and particularly to the transport method between a vacuum transport chamber and a processing chamber.

### BACKGROUND OF THE INVENTION

Heretofore, plasma etching or plasma CVD is accepted widely in the process of fabricating a semiconductor device such as a DRAM or a microprocessor. As one of the problems in working the semiconductor device utilizing plasma, cited is to reduce the number of foreign particles adhering to an object to be processed such as a wafer. For example, when foreign particles drop on a micro-pattern in the process of etching or before etching, the part is locally inhibited from being etched. As a result, defect such as disconnection is caused in the micro-pattern of the object to be processed to lower the yield. Therefore, a number of methods have been invented, in which the transport for the foreign particles is controlled using gas viscous force, thermophoretic force, Coulomb's force or the like to decrease the number of foreign particles adhering to the object to be processed.

In the method using the gas viscous force, it is invented that as described in Japanese Patent Application Laid-Open (JP-A) No. 2006-216710, before and after plasma processing, and in the process of transporting a wafer, gas is supplied from the upside of a processing chamber to form a down flow, and the transport for the foreign particles is controlled by this gas flow to prevent foreign particles from adhering to the wafer.

In generating a down flow in a processing chamber to transport the object to be processed, in order to prevent residual gas in the processing chamber or foreign particles from flowing into the transport chamber, it is necessary that gas is supplied to the transport chamber as well and the pressure in the transport chamber is a little set to positive pressure. When a gate valve between the processing chamber and the transport chamber is opened in the state where there is a large differential pressure between the processing chamber and the transport chamber, a sudden gas flow occurs, resulting in the risk that foreign particles fly. Accordingly, JP-A No. 2005-19960, for example, describes the necessity of holding down the differential pressure between the processing chamber and the transport chamber to open and close the gate valve.

On the other hand, U.S. 2006/0016559 A1 discloses that in a plasma processing apparatus where a shower plate is installed through a gas dispersion plate below an antenna, at least two kinds of processing gasses different in composition ratio or flow ratio of O₂ or N₂ are introduced into a processing chamber through different gas inlets of the inner area and the outer area of the gas dispersion plate in order to achieve in-plane uniformity of critical dimensions of an object to be processed while maintaining the in-plane uniformity of process depth of the object to be processed.

### SUMMARY OF THE INVENTION

With development into a micro-semiconductor device, it is necessary to decrease the number of foreign particles adhering to an object to be processed in the process of transporting an object to be processed or before and after transport to the utmost in order to cope with further progress in micro-structure.

In any of the above related art, it is not sufficiently taken into consideration to decrease the number of foreign particles adhering to an object to be processed in the process of transporting an object to be processed between a vacuum transport chamber and a processing chamber.

The present invention has been made in view of the above circumstances and provides a method for transporting an object to be processed in a semiconductor manufacturing apparatus, which may decrease the number of foreign particles adhering to the object to be processed in the process of transporting the object to be processed or before and after transport.

A typical example of the invention is shown in the following. That is, the invention provides a method for transporting an object to be processed in a semiconductor manufacturing apparatus, the apparatus including a processing chamber for processing an object to be processed, processing chamber gas supply means for supplying processing gas and transport gas to the processing chamber, processing chamber evacuating means for decompressing the processing chamber, a vacuum transport chamber for transporting the object to be processed in the processing chamber, transport chamber gas supply means for supplying transport gas to the vacuum transport chamber, vacuum transport chamber evacuating means for decompressing the vacuum transport chamber, and a gate valve provided between the vacuum transport chamber and the processing chamber, wherein, in when transporting the object to be processed while supplying the transport gas to the processing chamber and the vacuum transport chamber, respectively, wherein the method comprising steps of:

controlling the flow rate of the transport gas supplied to the processing chamber by the processing chamber gas supply means in a state to be twice or more the flow rate of the transport gas supplied to the vacuum transport chamber by the transport chamber gas supply means, and

opening the gate valve to transport the object to be processed between the vacuum transport chamber and the processing chamber in the state.

According to the present invention, the flow rates and pressure of gases in the transport chamber and the processing chamber are regulated to the optimum to adjust the flow of the gases, whereby the number of foreign particles adhering to the object to be processed in transporting can be decreased to improve the yield of a semiconductor device.

### BRIEF DESCRIPTION OF THE DRAWINGS

Preferred embodiments of the present invention will be described in detail based on the followings:

FIG. 1 is a diagram showing the principal part of a first embodiment in which a semiconductor manufacturing apparatus of the invention is applied to a plasma processing apparatus (a parallel-plate type UHF-ECR plasma etching apparatus);

FIG. 2 is a schematic diagram showing the whole of the plasma processing apparatus as the first embodiment, taken from above;

FIGS. 3A to 3F are diagrams functionally representing a program for performing “gas flow control” retained in a control computer of the first embodiment;

FIG. 4 is a diagram for explaining the outline of the processing sequence of the plasma processing apparatus as the first embodiment;

FIG. 5 shows the supply quantity, displacement and pressure in a processing chamber and a transport chamber, respectively in a timing A (the processing chamber and the transport chamber are separated from each other) in FIG. 4;

FIG. 6 is a diagram for explaining the flow when foreign particles are generated in the processing chamber;

FIG. 7 is a diagram showing the flow of the processing chamber interior gas and the locus of a foreign particle according to the invention;

FIG. 8 is a diagram showing the flow of gas in a timing B (in the transient state) in FIG. 4;

FIG. 9 is a diagram showing the vicinity of a first gate valve and a second gage valve to an enlarged scale of FIG. 8;

FIG. 10 is a diagram showing an example of a flow of gas after the second gate valve on the processing chamber side is opened to the fully opened state in a timing C in FIG. 4;

FIG. 11A is a diagram showing a typical example of a difference in locus of foreign particle in the case where the flow rate of gas supplied from a shower plate is constant and the exhaust speed is adjusted to set the pressure to low pressure and high pressure;

FIG. 11B is a diagram showing the part surrounded with the circle of FIG. 11A to an enlarged scale;

FIG. 12 is a diagram for explaining the drop speed of the foreign particle;

FIG. 13 is a diagram for explaining the drop speed of the foreign particle when the gas pressure is set high;

FIG. 14 is a diagram for explaining the condition where the pressure of gas in the processing chamber is regulated by a butterfly valve;

FIG. 15 is a diagram for explaining the condition where the pressure of gas in the processing chamber is regulated by a butterfly valve;

FIG. 16 is a diagram for explaining the gas pressure and the gas flow rate in a transport chamber in transporting an object to be processed;

FIG. 17A is a diagram for simply explaining the flow of gas in FIG. 10, which is a schematic diagram of the plasma processing apparatus, taken from the side;

FIG. 17B is a diagram for simply explaining the flow of gas in FIG. 10, which is a diagram of the plasma processing apparatus, taken from above;

FIG. 18A is a diagram for simply explaining the flow of gas in FIG. 16, which is a schematic diagram of the plasma processing apparatus, taken from the side; and

FIG. 18B is a diagram for simply explaining the flow of gas in FIG. 16, which is a diagram of the plasma processing apparatus, taken from above;

### DETAILED DESCRIPTION OF THE PREFERRED EMBODIMENTS

In the case of forming a flow of gas to control the transport of a foreign particle, when the gas pressure is set high, gas viscous force is also increased, so it is considered to be effective that the gas pressure is set high. It is, however, found from the study of the inventors that when the gas pressure is set high, conversely the number of foreign particles adhering to an object to be processed often increases.

In opening a gate valve disposed between a processing chamber and a transport chamber for transporting an object to be processed, it is desirable that gas is supplied to both of the processing chamber and the transport chamber, also the pressure on the transport chamber side is set higher than that on the processing chamber side, and further a pressure difference is held down ranging from several Pa to tens of Pa. According to the study of the inventors, however, it is found that such transport with a flow of gas makes an effect contrary to reduction of foreign particles depending on the supply quantity of gas.

According to the present invention, the flow rates and pressure of gases in the transport chamber and the processing chamber are regulated to the optimum to adjust the flow of gas, whereby the number of foreign particles adhering to an object to be processed in transporting is decreased.

According to a typical embodiment of the invention, in a semiconductor manufacturing apparatus including a processing chamber, an unit for supplying gas to the processing chamber, a first evacuating unit for decompressing the processing chamber, a transport chamber and an unit for supplying gas to the transport chamber, a second evacuating unit for decompressing the transport chamber and a gate valve provided between the processing chamber and the transport chamber, a process valve is installed on the processing chamber side from the gate valve in order to regulate the flow rates and pressure of gasses in the transport chamber and the processing chamber to the optimum to adjust the flows of gases. The pressure in the processing chamber before the gate valve is opened is set to negative pressure to the pressure in the transport chamber, a differential pressure between the transport chamber and the processing chamber is set to 10 pa or less, and further the flow rate of gas supplied to the processing chamber while the pressure in the processing chamber meets the requirement to range from 5 Pa to 50 Pa is set twice or more the flow rate of gas supplied to the transport chamber. Thus, in transporting the object to be processed while gas flows to the processing chamber and the transport chamber, respectively, the average flowing direction of gas in an area on the transport chamber side on the object to be processed points towards the transport chamber, so that the number of foreign particles adhering in transporting an object to be processed can be decreased to improve the yield of a semiconductor device.

### Embodiment 1

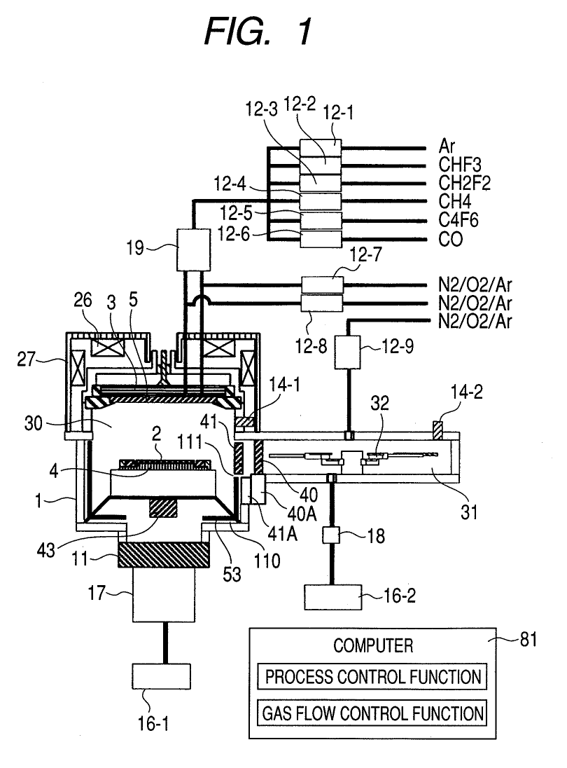

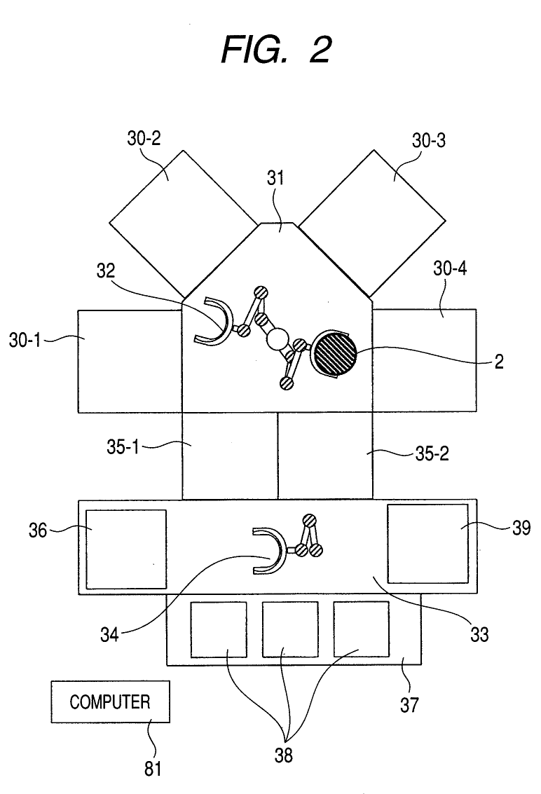

A first embodiment of a semiconductor manufacturing apparatus according to the invention will now be described with reference to the drawings. First, the outline of configuration of a semiconductor manufacturing apparatus to which the invention is applied will be described according to FIG. 1 and FIG. 2.

FIG. 1 shows the principal part of a first embodiment in which a semiconductor manufacturing apparatus of the invention is applied to a plasma processing apparatus (a parallel-plate type UHF-ECR plasma etching apparatus). FIG. 2 is a schematic diagram showing the whole of the plasma processing apparatus as the first embodiment, taken from above. FIG. 1 shows the outline of a vacuum side transport chamber 31 and one of the multiple of plasma processing chambers 30 in FIG. 2, taken from the side.

In this plasma processing apparatus, as shown in FIG. 2, four plasma processing chambers 30 (30-1˜30-4) are connected to one vacuum transport chamber 31. A vacuum transport robot 32 for transporting an object to be processed such as a wafer 2 is installed in the vacuum transport chamber, and an atmospheric transport chamber 33 is connected to the vacuum transport chamber 31 through two lock chambers 35 (a load lock chamber 35-1, an unload lock chamber 35-2). An atmospheric transport robot 34 for transporting the object to be processed and a wafer aligner 36 for detecting the notch position of the object to be processed and the center of the object to be processed while rotating the object 2 to be processed are installed in the atmospheric transport chamber 33. A wafer station 37 for installing a FOUP (Front Opening Unified Pod) 38 for storing an object to be processed is installed on the opposite side to the lock chamber 35 of the atmospheric transport chamber. Further, a wafer cleaner 39 for removing deposits adhering to the outer peripheral part of the back of the object to be processed is connected to the atmospheric transport chamber.

As shown in FIG. 1, the plasma processing chamber 30 has a double structure composed of an outer container (a vacuum chamber) 1 and an inner container, and includes an inner case 53 constituting a side wall of the processing chamber as the inner container and constituting the lower part of the processing chamber. An upper inner case is not illustrated. Further, the chamber 30 includes: an antenna 3 disposed on the upside of the vacuum chamber 1 to supply high-frequency power for generating plasma, a shower plate 5 having a dispersion plate for dispersing and supplying the processing gas into the plasma processing chamber 30, a sample placing electrode 4 disposed in the plasma processing chamber 30 to place an object 2 to be processed on the placing surface and process the same, and a vertical driving mechanism 43 for the sample placing electrode 4. The inner case 53 replaceably disposed in the interior of the vacuum chamber of the processing chamber 30 is a replacement part for efficiently performing periodic dismantle and cleaning. Further, a turbo-molecular pump 17 is mounted, in the plasma processing chamber 30, as evacuating means for decompressing the interior of the chamber. In order to control the pressure in the processing chamber, a butterfly valve 11 is mounted on the upside of the turbo molecular pump 17. On the other hand, a dry pump 16-1 is put in the connecting state downstream from the turbo molecular pump. Further, a coil 26 and a yoke 27 for forming a magnetic field are also provided on the plasma processing chamber 30. The processing chamber 30 and the transport chamber 31 are provided with vacuum gauges 14-1 and 14-2, respectively. A first gate valve 40 is placed in a transport passage for an object to be processed between the plasma processing chamber 30 and the vacuum transport chamber (hereinafter the vacuum transport chamber is referred to as a transport chamber simply when distinction from the atmospheric transport chamber is not required) 31. A second gate valve (a process valve) 41 is placed on the processing chamber side to the first gate valve 40.

The first and second gate valves 40, 41 are respectively controlled to open and close by actuators 40A, 41A utilizing a working source such as pneumatics. When the second gate valve 41 is in the totally closed state, it is located in the same radial position as the inner wall of the processing chamber 1, and when the valve is in the state of being opened by the actuator 41A, it is moved outside the inner wall in the radial direction.

In the plasma processing apparatus, the whole apparatus is automatically controlled by a control computer 81, various actuators and various sensors. That is, the control computer 81 includes a CPU, a memory, an external storage device holding a program and data, and an input/output means (a display, a mouse and a keyboard), and automatically controls the whole apparatus by executing a series of processing related to the plasma processing for an object to be processed according to the program. Data such as a wafer transport recipe, a processing recipe, and a gas supply recipe are held in the storage device of the control computer 81. The wafer transport recipe is a recipe concerning the transport procedure of transporting a wafer between the hoop 38, the atmospheric transport chamber 33, the lock chamber 35, the vacuum transport chamber 31 and each vacuum processing chamber 30, the processing recipe is a recipe concerning the procedure for processing a wafer in each vacuum processing chamber 30, and the gas supply recipe is a recipe concerning the kind and supply quantity of gas supplied to the vacuum transport chamber 31, each vacuum processing chamber and further the atmospheric transport chamber for transporting and processing a wafer. As another program, a series of programs related to an ordinary plasma processing are held. The invention is characterized in that the control computer 81 has “a process control function” and “a gas flow control function”. In the invention, among various kinds of functions required for transporting and processing an object to be processed such as a wafer in a plasma processing apparatus, the functions other than the above “gas flow control function” are collectively defined as a process control function.

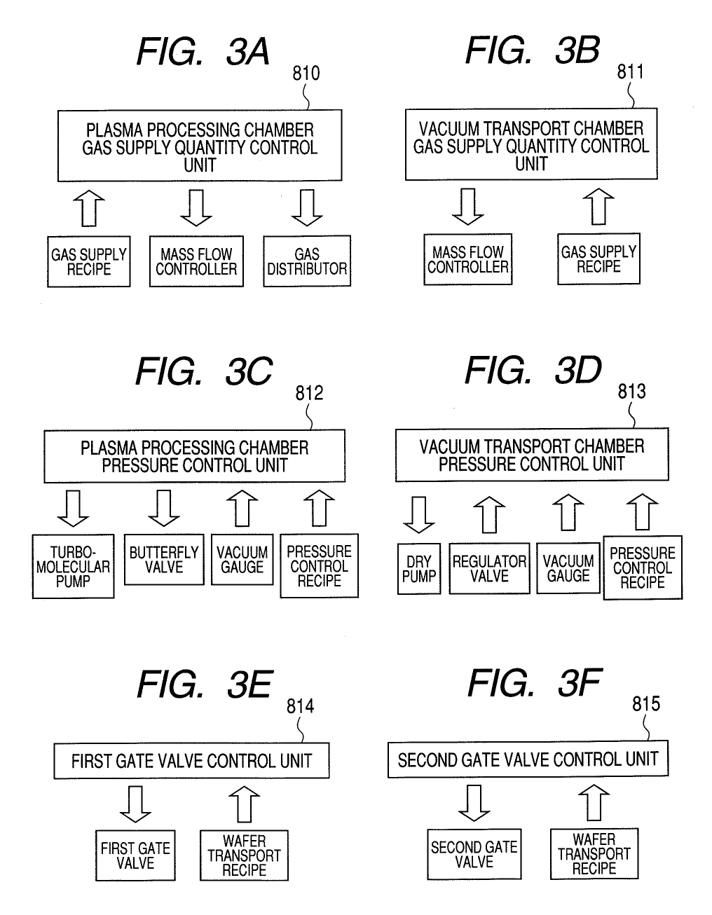

A program for achieving this “gas flow control function” is, as shown in FIG. 3, represented as the multiple of units. The respective units shown in FIGS. 3A to 3F represent the functions achieved by executing a program, and taking the values of various kinds of sensors such as a pressure sensor as input to operate various kinds of actuators such as a mass flow controller, and first and second gate valves as units. That is, “the gas flow control function” is achieved by executing the respective program elements of a plasma processing chamber gas supply quantity control unit 810, a vacuum transport chamber gas supply quantity control unit 811, a plasma processing chamber pressure control unit 812, a vacuum transport chamber pressure control unit 813, a first gate valve control unit 814, and a second gate valve control unit 815, and performing the cooperative operation with the corresponding actuator and sensor based on the respective predetermined data. As an example, the plasma processing chamber pressure control unit 812 conducts the processing for changing the opening of the butterfly valve 11 according to a measured value of the vacuum gauge 14-1 to maintain the pressure in the processing chamber to a predetermined value preset according to the pressure control recipe and adjusting exhaust conductance.

The first gate valve 40 has a function of completely performing vacuum lock, and the coming and going of gas between the processing chamber and the transport chamber is completely shut off by closing the first gate valve. On the contrary, the second gate valve 41 has the purpose of making the side walls axially symmetric about an electromagnetic wave not to cause eccentricity of plasma and the purpose of relaxing flying of foreign particles due to a sudden flow of gas caused by a differential pressure between the processing chamber and the transport chamber. Therefore, the second gate valve has a little clearance gap 111 between the second gate valve 41 and the processing chamber 30 even in the closing state not to have a function of completely sealing the gas. The clearance gap 111 between the second gate valve and the processing chamber approximately ranges from tens of μm to several mm.

The plane antenna 3 for radiating electromagnetic waves is installed parallel to the sample placing electrode 4 for placing an object 2 to be processed on the upside of the processing chamber 30. A discharge power supply (not shown) for generating plasma and a high-frequency bias power supply (not shown) for applying bias to the antenna 3 are connected to the antenna 3. A bias power supply (not shown) for accelerating ions entering the object 2 to be processed is connected to the placing electrode 4. The sample placing electrode 4 is moved up and down by the vertical driving mechanism 43. The shower plate 5 is placed through a gas dispersion plate under the antenna 3, and the processing gas is supplied into the processing chamber through a gas hole (not shown) provided in the shower plate 5. The gas dispersion plate is divided into two areas, an inner area and an outer area, in the radial direction, thereby controlling the flow rate and composition of gas supplied from a processing gas source in the inner area and in the outer area of the gas dispersion plate independently, that is, the vicinity of the center of the object to be processed and the vicinity of the outer periphery thereof. The constitution of the thus constructed gas dispersion plate is disclosed in JP-A No. 2006-41088, for example.

The flow rate of the processing gas supplied into the plasma processing chamber is controlled by the plasma processing chamber gas supply control unit 810. That is, the flow rate of gas supplied into the processing chamber 30 through the shower plate is controlled by the multiple of mass flow controllers 12-1 to 12-8 controlled by the control computer 81. The gas dispersion plate is divided into two areas, an inner area and an outer area in the radial direction in order that the flow rates and compositions are independently controlled mutually by the processing gas supplied from the inner area in the radial direction and the processing gas supplied in the outer area from that in the in-plane of the shower plate, and the processing gasses are divided at predetermined flow ratios by a gas distributor 19 to supply the gasses to the respective areas.

As the gas introduced into the processing chamber 30, cited are Ar, CHF₃, CH₂F₂, CF₄, C₄F₆, C₄F, C₅F, CO, O₂, N₂, CH₄, CO₂, and H₂. Among these processing gasses, Ar, CF₄, C₄F₆, C₄F₈, C₅F₈, CHF₃, CH₂F₂, CO, CH₄, H₂ respectively flow at a predetermined flow rate in the gas flow rate controllers 12-1 to 12-6 to reach the gas distributor 19. The gas reaching the gas distributor 19 (the processing gas) is distributed to the gas introduced from the gas hole in the inner area of the shower plate 5 and the gas introduced from the gas hole in the outer area at a predetermined flow ratio in the gas distributor 19.

The N₂ or Ar as carrier gas introduced into the processing chamber 30 is controlled to a predetermined flow rate by the gas flow rate controllers 12-7 and 12-8, and distributed to the gas introduced through the gas hole of the inner area of the shower plate 5 and the gas introduced through the gas hole of the outer area at a predetermined flow ratio.

Concerning the constitution for controlling the respective flow rates of the processing gas and carrier gas, the constitution described in JP-A No. 2006-41088 is adopted, so the detailed description is omitted.

A passage (a clearance gap) 110 allowing gas to flow is intentionally made between the inner case 53 and the body of the processing chamber, and as described later, some of gas flowing from the transport chamber into the processing chamber may be released not through the interior of the processing chamber, but through the clearance gap by the turbo molecular pump 17. The size of a gas passage between the inner case and the processing chamber body is determined so that the exhaust conductance of the clearance gap 110 is larger than the conductance of the clearance gap 111 of the second gate valve when the second gate valve is closed.

The gas supply to the transport chamber is controlled by the vacuum transport chamber gas supply quantity control unit 811. That is, in order to supply a predetermined flow rate of nitrogen or rare gas such as argon as carrier gas into the transport chamber, or supply the drying air, these gases can be supplied into the transport chamber 31 through the mass flow controller 12-9 controlled by the control computer 81. The gas supply port is set above the vicinity of the circumferential rotating axis (approximately the center of the transport robot) of the transport robot. The dry pump 16-2 is connected to the transport chamber 31 for decompressing the interior of the transport chamber. In evacuation while flowing the gas, in order to control the interior of the transport chamber to predetermined pressure, an exhaust conductance adjusting valve 18 having a function of adjusting the exhaust conductance and controlled by the control computer 81 is installed in the exhaust line.

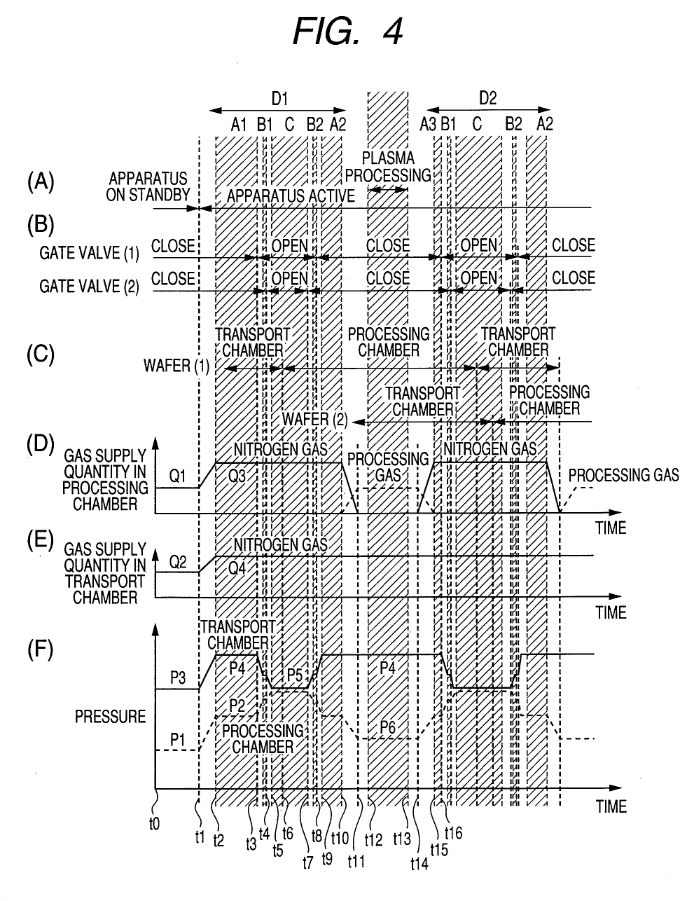

The outline of a processing sequence of the plasma processing apparatus according to the invention, especially the timing of permitting gas to flow by a foreign particles control function of a gas flow will now be described by FIG. 4. FIG. 4, (A) shows a process state of the apparatus, FIG. 4, (B) shows the opening and closing states of the valve, FIG. 4, (C) shows the transport state of a wafer, FIG. 4, (D) shows the state of a gas supply quantity in the processing chamber, and FIG. 4, (E) shows the state of a gas supply quantity in the vacuum transport chamber. FIG. 4, (F) shows the state of pressure in the processing chamber and in the vacuum transport chamber. FIG. 4 shows only the relationship between one specified vacuum processing chamber and a vacuum transport chamber as shown in FIG. 1. The relationship between some other vacuum processing chamber and the vacuum transport chamber will be the same. A control method for the gas pressure and the gas flow rate in the respective states of FIG. 4, (A) to (F) will now be described.

In the case where the plasma processing apparatus is on standby (Time=t0 to t1), for example, the nitrogen gas as the carrier gas is put in the state of flowing at a flow rate of Q1cc/min in the processing chamber 30, and flowing at a flow rate of Q2cc/min. At this time, the pressures of the processing chamber and the transport chamber are taken as P1 and P3, respectively. The nitrogen gas is supplied from the shower plate in the processing chamber, and supplied from the gas supply port at the central upside in the vacuum transport chamber. Before the start of transporting the first wafer (1) to be processed, the flow rates of nitrogen gas supplied to the processing chamber and the transport chamber are increased to Q3cc/min and Q4cc/min (Q3>Q4×2), respectively (t1 to t2). At this time, the exhaust speed is controlled so that the pressures in the processing chamber and the transport chamber are P2 and P4 (P4−P2<10 Pa, 5 Pa≦P2≦50 Pa).

Subsequently, the first wafer (1) is carried from the load lock chamber into the vacuum transport chamber 31. Subsequently, the first gate valve 40 is opened (t3). The first gate valve 40 is opened, thereby putting the transport chamber and the processing chamber in the state of partially conducting through a clearance gap 111 around the second gate valve 41 so that the difference in pressure between both chambers is gradually reduced. Further, with a little delay, for example, in the lapse of 0.5 sec to 1 sec, the second gate valve is opened (t4), and further the opening is sequentially increased to enter the fully open state (t5), thereby substantially equalizing the values of pressures in the processing chamber and the transport chamber, P5, for example, (to be exact, the pressure in the transport chamber is a little higher than that in the processing chamber). With the pressures in the processing chamber and the transport chamber substantially equal to each other, the first wafer (1) 1 is carried from the vacuum transport chamber 31 in the processing chamber (t6), and further placed on the placing surface on the placing electrode 4. After that, the second gate valve is closed (t7) and further the first gate valve is closed (t8). Subsequently, in order to perform predetermined processing by plasma in the processing chamber, while the flow rate of nitrogen gas (carrier gas) is gradually decreased to zero, the supply quantity of processing gas to the processing chamber is gradually increased (t10 to t11). The processing gas is supplied from the shower plate. With this supply, the pressure in the processing chamber is controlled to the pressure P6 of the plasma processing condition. On the other hand, the pressure in the transport chamber is returned to P4. In the meantime, a fixed quantity of nitrogen gas is continuously supplied to the transport chamber. The plasma processing to the first wafer (1) is started (t12), and after the end of a predetermined processing (t13), while the supply quantity of processing as to the processing chamber 30 is gradually decreased, the supply quantity of nitrogen gas is gradually increased (t14 to t15). The reason why the supply quantities of these gases are increased and decreased is the restrain of foreign particles from flying due to a sudden change in the gas flow.

While the first wafer (1) is processed, the next wafer (2) is carried from the load lock chamber in the vacuum transport chamber 31. In carrying out the processed first wafer (1) from the processing chamber and carrying the unprocessed next wafer (2) into the chamber, subsequently the first gate valve is opened (t16), and further the second gate valve is opened. After this, similarly to carry in-and-out of the first wafer (1), the similar steps are repeated for carry in-and-out of the next wafer (2). The processed first wafer (1) is separately collected in a hoop in an atmosphere of air through the lock chamber and so on.

The flow rate characteristic and pressure characteristic of gas in the processing chamber and the flow rate characteristic and pressure characteristic of gas in the transport chamber shown in FIG. 4 are examples, and needless to say, the characteristics may be replaced with another characteristic including a non-linear part within the scope according to the aspect of the invention.

In putting the plasma processing apparatus in the standby state, the gasses are kept flowing at flow rates of Q3cc/min and Q4cc/min, for example, respectively in the processing chamber and the transport chamber until a predetermined time passes away after the last wafer is carried out, and after that, the apparatus is on standby with the flow rates of gasses reduced to Q1cc/min and Q2cc/min, for example, for reduction of the cost.

In the invention, the foreign particles control by the gas flow is conducted during the active state of the plasma processing apparatus and also for the transport timings D1, D2 in FIG. 4 in which the plasma processing is not conducted. Each transport timing D includes timings A1, B1, B2, C, A2, A3.

In the transport timing D1, the timing A1 is the state where the first wafer (1) is carried in the vacuum transport chamber 31 through the lock chamber and so on. The timing B1 is equivalent to the state after the first gate valve 40 is opened prior to carrying an unprocessed first wafer (1) from the interior of the vacuum transport chamber 31 into the processing chamber 30, and also immediately before the second gate valve 41 is opened. The timing C is the state where both the second gate valve 41 and the first gate valve 40 are fully opened so that the pressures in the vacuum transport chamber and the processing chamber are substantially at the same level, and the unprocessed first wafer (1) is transported between both chambers. The timing B2 is the state where in order to put the vacuum transport chamber and the processing chamber in the non-conducting state after the end of carrying the first wafer (1) into the processing chamber 30, the second gate valve 41 is closed immediately before the first gate valve 40 is closed. The timing A2 is the state before the start of introducing the processing gas while releasing the nitrogen gas from the interior of the processing chamber 30. During the plasma processing for the first wafer (1) in the processing chamber 30, the next unprocessed wafer (2) is carried into the vacuum transport chamber 31 through the lock chamber. The timing A3 in the transport timing D2 is the state before the processed first wafer (1) is carried from the processing chamber into the vacuum transport chamber, the timing B1 is the state of opening the first gate valve 40 immediately before the second gate valve 41 is opened prior to carrying out the processed first wafer (1) from the processing chamber into the vacuum transport chamber and also carrying the next unprocessed wafer (2) from the interior of the vacuum transport chamber into the processing chamber. The timing C is the state where both of the second gate valve 41 and the first gate valve 40 are fully opened, and with the vacuum transport chamber and the processing chamber substantially equalized in pressure, the processed first wafer (1) and the next unprocessed wafer (2) are alternately carried between both chambers. The timing B2 is the state where the second gate valve 41 is closed immediately before the first gate valve 40 is closed in order to put the vacuum transport chamber and the processing chamber in the non-conducting state after the end of carrying the next wafer (2) into the processing chamber 30. The timing A2 in the transport timing D2 is the state of discharging the nitrogen gas from the interior of the processing chamber 30 before the start of introducing the processing gas.

In the timing A (A1, A2, A3), the first and second gate valves 40, 41 are both closed, and the processing chamber and the transport chamber are separated from each other. The timing B is the transient state where the processing chamber and the transport chamber are put in the conducting state or in the non-conducting state, and although the first gate valve is opened, the second gate valve is closed. In the timing B1, the first gate valve 40 is opened, and after that, the second gate valve 41 is opened. In the timing B2, the opening and closing order of the valves is reversed. In the timing C, the first and second gate valves 40, 41 are both opened, and the processing chamber and the transport chamber are in the conducting state.

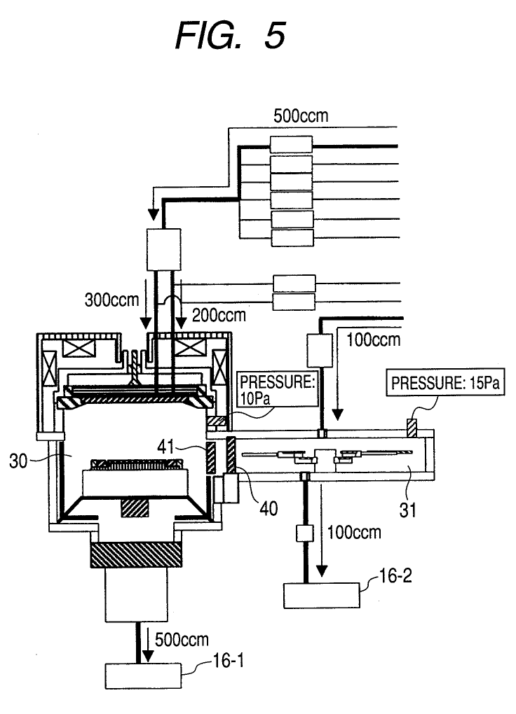

FIG. 5 shows examples of supply quantity, exhaust quantity and pressure of gas in the processing chamber and the transport chamber, respectively in the timing A (A1, A2, A3) in FIG. 4, in other words, in the state where the processing chamber and the transport chamber are separated from each other. That is, it shows the state before the start of carrying an object to be processed from the interior of the vacuum transport chamber 31 into the processing chamber 30, the state after the second gate valve and the first gate valve are closed after the end of carrying the object to be processed into the interior of the processing chamber, or the state before the start of carrying out the object to be processed from the interior of the processing chamber. In the gas supply system, gas piping, which does not supply gas is indicated by a thin line, and gas piping where gas flows is indicated by a thick line. In the condition of FIG. 5, the gas supply quantity and pressure to the processing chamber and the transport chamber are controlled independently of each other. First, nitrogen gas of Q3=500 ccm(cc/min) is supplied to the processing chamber. In the nitrogen gas of 500 ccm, the quantity of gas supplied from the inside of the shower plate is 300 ccm, and the quantity of gas supplied from the outer area of the shower plate is 200 ccm. The reason why the flow rate of nitrogen gas supplied from the inside of the shower plate is increased is that on the wafer surface placed on the sample placing electrode, the flow velocity of gas in the radial direction is increased. On the contrary, the reason why the gas is supplied from the outer area of the shower plate as well is that the foreign particles adhering to the inside of the gas hole and the vicinity of the gas hole in the shower plate are pushed away by the flow of gas. The pressure P2 in the processing chamber is set to 10 Pa, and the exhaust conductance is adjusted by the opening of the butterfly valve to control the pressure.

In the transport chamber, the nitrogen gas is supplied by Q4=100 ccm, and the nitrogen gas is released by the dry pump. The pressure P4 in the transport chamber is controlled to be 15 Pa by the opening of the valve 18.

The foreign particles control function by the gas flow according to the invention, which may be achieved by utilizing the processing chamber gas supply control function 810 and the transport chamber gas supply control function 812, will now be described.

First, the foreign particles transport control by the gas flow will be simply described. In order to prevent adhesion of foreign particles to an object to be processed in the process of transporting the object to be processed and before and after transporting, it is effective to control the transport of foreign particles by the flow of gas. Supposing that the processing chamber and the transport chamber are highly evacuated without supplying gas, when foreign particles are generated, the motion of the foreign particles is determined by the initial velocity, the gravity drop and reflection on the wall or the like.

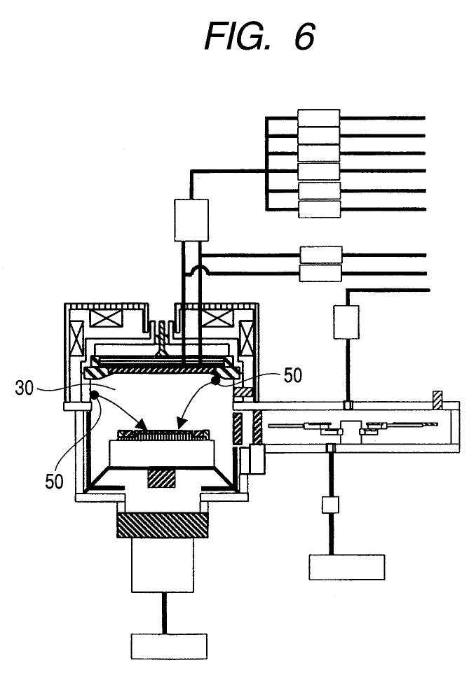

As shown in FIG. 6, for example, when the foreign particles 50 are generated in the direction of dropping on the object to be processed placed on the sample placing electrode from the side wall and the top plate part of the shower plate or the like, the foreign particles drop on the object to be processed, and adhere thereto at a certain probability of adhesion to contaminate the object to be processed.

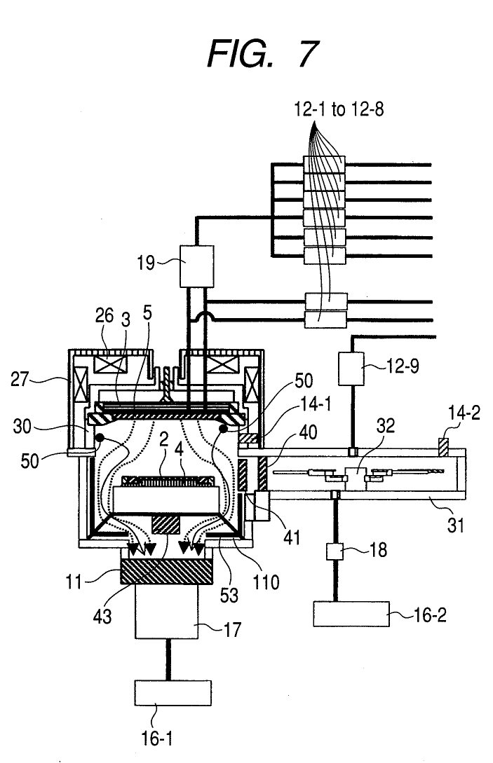

On the contrary, according to the foreign particles control function by the gas flow according to the invention, the gas is let flow from the shower plate, thereby producing a down flow in the processing chamber and also in the space above the wafer, the flow of gas directing outwards substantially from the center of the wafer is produced, whereby the foreign particles 50 generated due to separation from the interior of the processing chamber are transported on the flow of gas not to adhere to the object to be processed. In FIG. 7, the curves shown in broken lines in the processing chamber indicate the flow of gas, and the curves shown in solid lines indicate the locus of foreign particles.

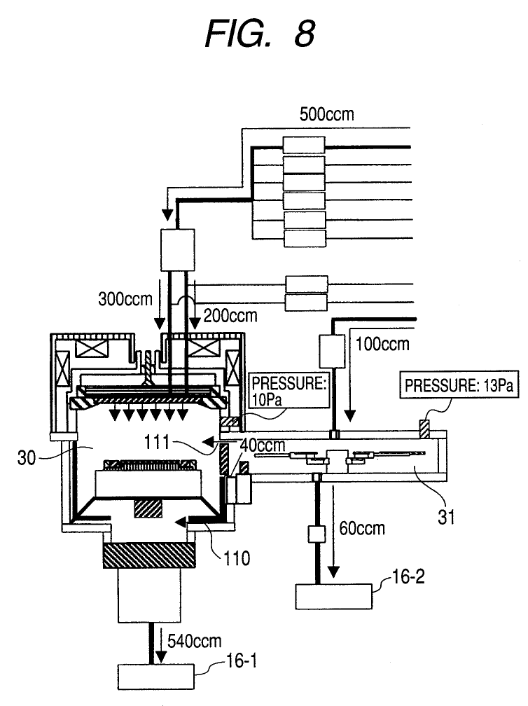

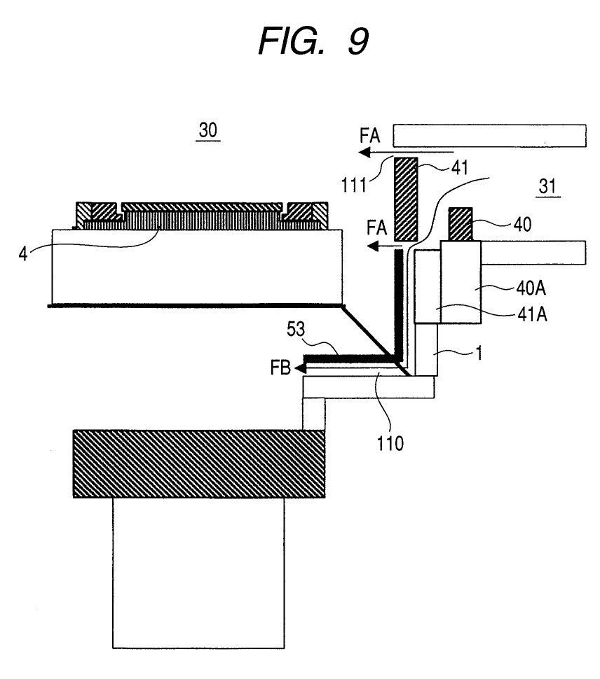

The flow of gas in the timing B (the transient state) in FIG. 4 will now be described using FIG. 8 and FIG. 9. FIG. 9 is a diagram showing the vicinity of the first gate valve and the second gate valve in FIG. 8 to an enlarged scale.

Before the first gate valve 40 is opened, while the pressure in the processing chamber is 10 Pa, the pressure in the transport chamber is 15 Pa, so that when the first gate valve 40 is opened with the second gate valve 41 opened, there is the probability that a sudden flow of gas occurs due to the differential pressure in the processing chamber so that the foreign particles fly up. However, in the case where the second valve 41 is in the closed state when the first gate valve 40 is opened, some of gas flowing into the space between the first gate vale 40 and the second gate valve 41 gradually flows into the processing chamber through the clearance gap 111 around the second gate valve 41 (arrows FA in FIG. 9) and also some of gas is released by the turbo molecular pump through the clearance gap 110 between the inner case 53 and the object body to be processed (an arrow FB in FIG. 9). Therefore, the generation of a sudden gas flow in the processing chamber can be restrained. Although an account of the pressure in the processing chamber is given by 10 Pa similarly in FIG. 5 and FIG. 8, to be exact, the pressure in the state of FIG. 8 is a little higher.

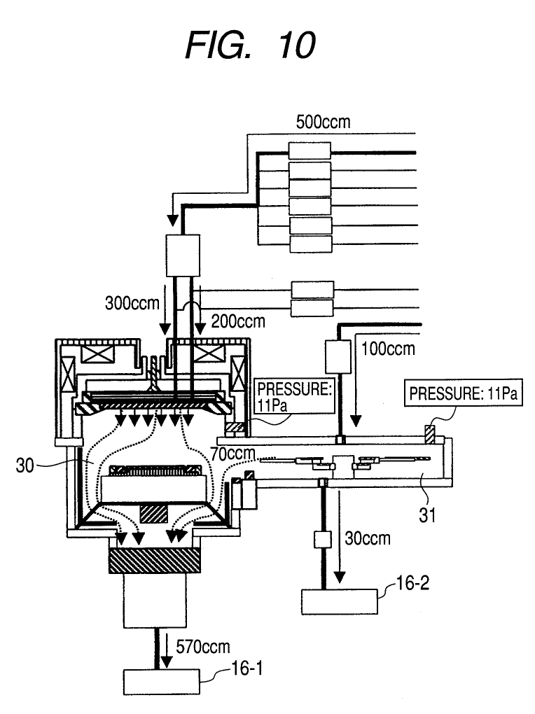

The timing C (the processing chamber and the transport chamber are in the conducting state) of FIG. 4 will now be described. FIG. 10 shows an example of a gas flow after the second gate valve 41 on the processing chamber side is opened to the fully opening state in the timing C. In the case of 100 ccm of nitrogen gas supplied to the transport chamber, the greater part, about 70 ccm of nitrogen gas flows into the processing chamber side, the remaining about 30 ccm is released by the dry pump 16-2 installed on the transport chamber side. This results from that the exhaust capability of the exhaust system on the processing chamber side is larger than that of the exhaust system on the transport chamber side. The pressure is about 11 Pa, substantially equal both in the processing chamber and the transport chamber. To be exact, however, it is a little positive pressure on the transport chamber side.

In the state (See FIG. 4) of the timing C shown in FIG. 10, the respective objects to be processed are transported from the transport chamber to the processing chamber, or transported from the processing chamber to the transport chamber. Also at this time, the foreign particles control function by the gas flow is exhibited. That is, the flow of nitrogen gas supplied from the shower plate into the processing chamber is controlled, whereby the foreign particles can be transported on the flow of gas not to adhere to the object to be processed on the sample placing electrode.

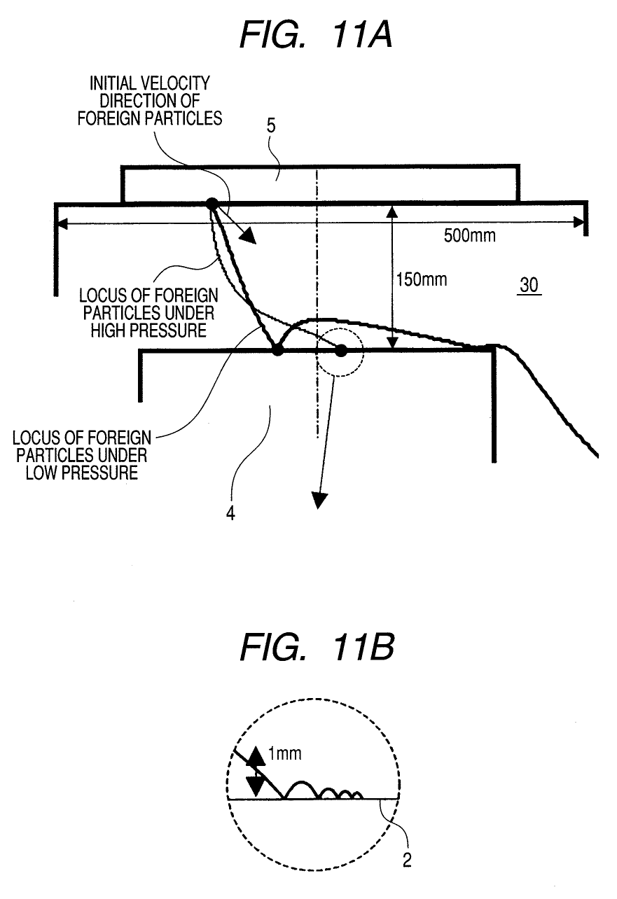

The optimum range of the flow rate of gas and pressure in the processing chamber to be controlled by the processing chamber gas supply control function 810 in order to surely achieve the foreign particles control function by the gas flow according to the invention will now be described. The gas viscous force is more increased as the speed of gas to the foreign particle is higher and the pressure of gas is higher. Therefore, when the pressure of gas is increased, for example, the foreign particle is more surely transported on the flow of gas so that the adhesion amount of foreign particles to the object to be processed might be decreased. However, “carried on the flow of gas” and “decrease in number of foreign particles adhering to the object to be processed” are not always consistent with each other. This is shown using FIGS. 11A and 11B.

FIG. 11A shows a typical example of a difference in locus between the foreign particles in the case where the flow rate of gas supplied from the shower plate 5 is set constant, and the exhaust speed is adjusted to set the pressure to a low pressure as much as 5 Pa or less and to a high pressure as much as tens of Pa. In FIG. 11A, it is supposed that the foreign particles are generated by separation from the surface of the shower plate 5, and the initial velocity points the bottom right-hand corner. In the case of a low pressure, the foreign particles drop while being let flow by the flow of gas, bound on the surface of the wafer to be processed on the sample placing electrode 4, subsequently bound up to the height of several cm from the wafer, again are let flow largely to the right by the flow of gas, next bound at the edge of the sample placing electrode 4, and lastly the particles are transported toward the port of the exhaust pump. On the other hand, in the case of a high pressure, the first drop point to the wafer to be processing is at the right of that in the case of a low pressure. This results from that as compared with the case of a low pressure, the foreign particles are easier to be carried on the flow of gas. However, as shown to an enlarged scale in FIG. 11B, since the bounding height of the foreign particles is small as much as 1 mm or less, the particles bound several times near the first bound position on the surface of the wafer 2, and finally adhere to the wafer.

Such a difference in bounding height of foreign particles between the high pressure and the low pressure largely depends on the drop velocity of the foreign particles immediately before bounding. The drop velocity of the foreign particles simply gradually approaches such a velocity that the downward accelerating force by gravity and the resistance force by the gas viscous force balance.

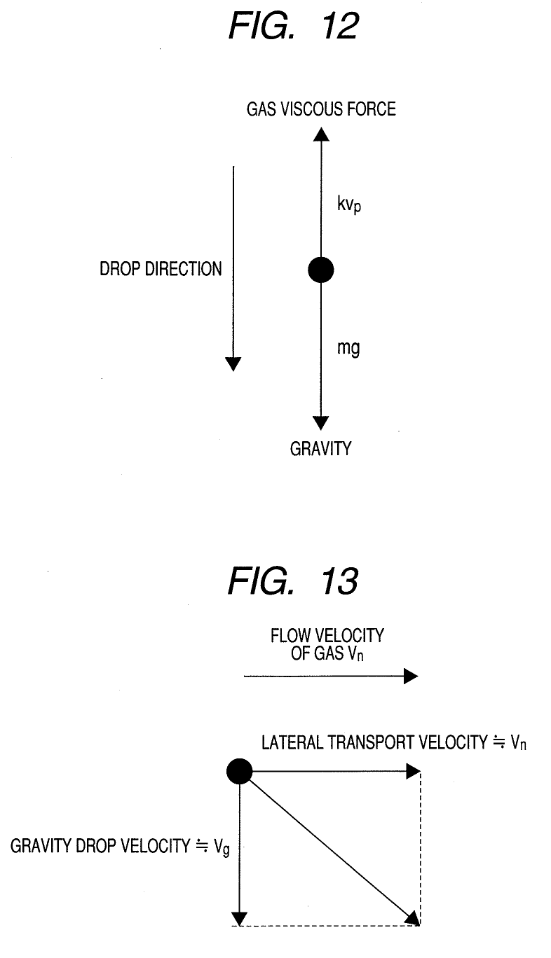

This drop velocity will be described using FIG. 12 and FIG. 13. In this case, it is supposed for simplification that the flow of gas is ignorable. The foreign particles drop under the gravity mg, and on the other hand, they are subjected to the resistance force (the gas viscous force) kvₚ of gas depending on the drop velocity vₚ of foreign particles. Thus, the foreign particles finally approach such a velocity that the acceleration by the gravity and the resistance force of gas balance. When the velocity in the balanced forces is taken as the gravity drop velocity, and this is taken as vg, the following formula holds.

mg=kv_{g} (1)

In this case, m is mass of foreign particles, g is gravity acceleration, which is about 9.8 m/s², and k is a proportional constant indicating the gas viscous force.

For example, in the case of particulate having a particle diameter of 1 μm and density of 2.5 g/cm³, although under the pressure of 50 Pa, the drop velocity of foreign particles when the drop by gravity and resisting force by the gas viscous force balance is about 0.1 m/s, it is lowered to about 0.01 m/s under the pressure of 100 Pa.

Therefore, the more the gas pressure is increased, the more the drop velocity immediately before dropping on the object to be processed becomes lower, so that the velocity after bounding also becomes lower, resulting in the impossibility of bounding high. That is, when the gas pressure is increased, the effect of transporting the foreign particles carried on the flow of gas becomes larger. However, once the foreign particles enter the wafer, the probability of adhesion to the vicinity of the first drop point becomes higher. Accordingly, in increasing the gas pressure, it is necessary to increase the gas flow velocity enough to compensate for the demerit due to increase in gas pressure.

As the gas flow rate, as shown in FIG. 13, for example, it is preferable that the velocity of foreign particles carried on the flow of gas parallel to the object to be processed is higher than the drop velocity by gravity.

In this case, when the flow velocity of gas parallel to the object to be processed is Vₙ, it is expressed by the formula (2).

Vₙ>V_{g} (2)

In this case, when the foreign particle diameter is 1 μm and the gas pressure is 50 Pa, the drop velocity is, as already described, about 0.1 m/s, so preferably the flow velocity of gas is 0.1 m/s or more. When the V_{g} is replaced with the gas pressure, substantially the relationship is expressed by the formula (3).

Vₙ>P/500 (3)

In the case of a plasma processing apparatus for processing a wafer having a diameter of 300 mm, the diameter of the inner wall of the processing chamber is about 500 mm, and in this case, at a gas flow rate of 500 ccm, for example, the gas pressure is 50 Pa, and the gas velocity on the surface of the object to be processed is about 0.1 m/s, so preferably the gas pressure does not exceed 50 Pa. That is, when the gas flow rate is fg (unit is ccm, or ml/min), the relationship between the pressure (the unit is Pa) and the gas flow velocity is expressed as shown in the following formula (4). Although the coefficient 10 of the right side of the formula (4) is a value inherent to the apparatus, the relational expression (4) may be applied in the etching device for processing the wafer having a diameter of 300 mm.

f_{g}>P×10 (4)

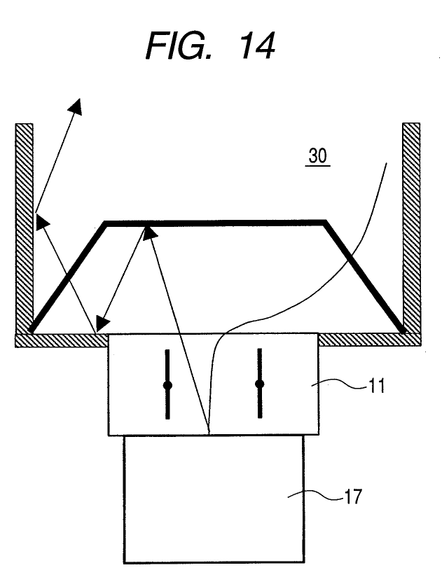

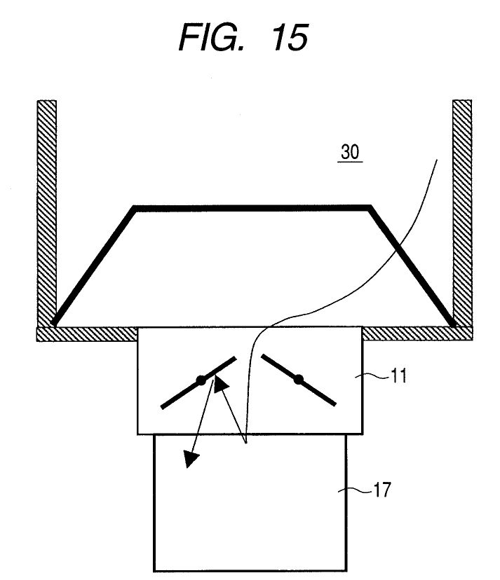

The lower limit in the case of lowering the pressure will now be described using FIG. 14 and FIG. 15. The pressure of gas in the processing apparatus is adjusted by regulating the opening and closing degree of the blade of the butterfly valve 11. Although it is necessary to increase the opening of the butterfly valve in order to lower the gas pressure, the increase in opening degree of the butterfly valve 11 produces reverse effect from the viewpoint of reducing the foreign particles, which will be described. In the turbo molecular pump 17, the blades are rotated at high speed in the interior, and the speed reaches 300 m/s, for example. On the contrary, the velocity of the foreign particles is 1 m/s, for example, so that the foreign particles having such a low speed are flied about at a high speed by the blades of the turbo molecular pump 17 to scatter in the processing chamber as shown in FIG. 14. Since the velocity of foreign particles rebounded at a high speed is very high, the foreign particles are never decelerated by the viscous force of gas, so that they may easily reach the wafer.

FIG. 15 shows an example of a locus of foreign particles in the case of lowering the opening of blades of the butterfly valve 11 to regulate the pressure. In the example of FIG. 15, high-speed foreign particles rebounded by the blades of the turbo molecular pump 17 are reflected on the blades of the butterfly valve to again enter the turbo molecular pump while high speed is kept. The foreign particles entering the turbo molecular pump 17 pass through the blades of the turbo molecular pump to be released as they are.

From the comparison between FIG. 14 and FIG. 15, it is found that the blade itself of the butterfly valve 11 acts as a baffle for preventing scattering of the foreign particles. Therefore, the smaller the opening of the butterfly valve 11 is (the blades are closed), the better. When this is replaced with the relationship between the pressure and the flow rate, supposing that the pressure is 10 Pa or more at the gas flow rate of 500 ccm, and it is 20 Pa or more at the gas flow rate of 1000 ccm, the opening of the butterfly valve should be necessarily reduced. That is, it is also important to determine the flow rate of gas and the pressure so that the opening of the butterfly valve is made smaller.

In order to achieve the foreign particles control function by the gas flow according to the invention, at least in transporting the object to be processed, the gas pressure and the gas flow rate in the transport chamber to be controlled by the processing chamber gas supply control function 810 and the transport chamber gas supply control function 812 will now be described. In opening the first gate valve and the second gate valve (hereinafter referred to as the gate valves simply), in order to prevent residual gas and foreign particles in the processing chamber from entering the processing chamber, the transport chamber should be positive pressure to the processing chamber. However, in the case where the pressure in the processing chamber is 5 to 55 Pa, when the pressure in the transport chamber is higher than that in the processing chamber by 10 Pa or more, there is the risk that the foreign particles are flied up due to a sudden flow of gas generated at the moment of opening the gate valve. Therefore, preferably the pressure difference is 5 Pa to 10 Pa. When a foreign particle is generated on the transport chamber side in the open state of the gate valve, the foreign particle is carried on the flow of gas to flow into the processing chamber side.

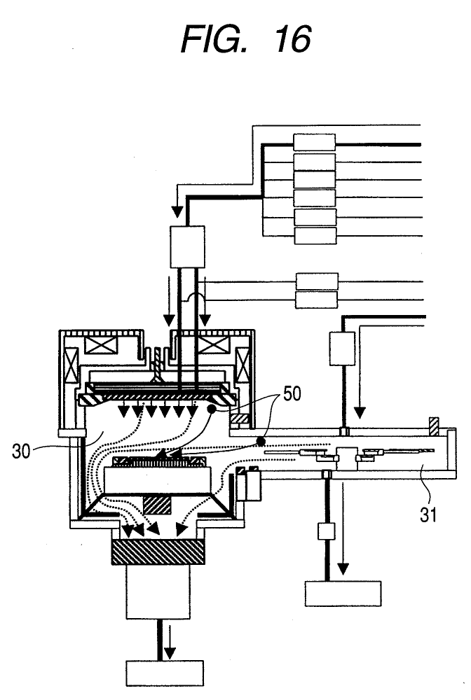

At this time, when such a gas flow to pass above the electrode is produced by influence of gas flowing in from the transport chamber as shown in FIG. 16, foreign particles flowing in from the transport chamber and foreign particles generated from the side wall at the side of the gate valve in the processing chamber highly probably adhere to the object to be processed. It is necessary to produce a gas flow distribution such that desirably the gas flowing in from the transport chamber passes under the electrode to flow in the turbo molecular pump 17 as shown in FIG. 10.

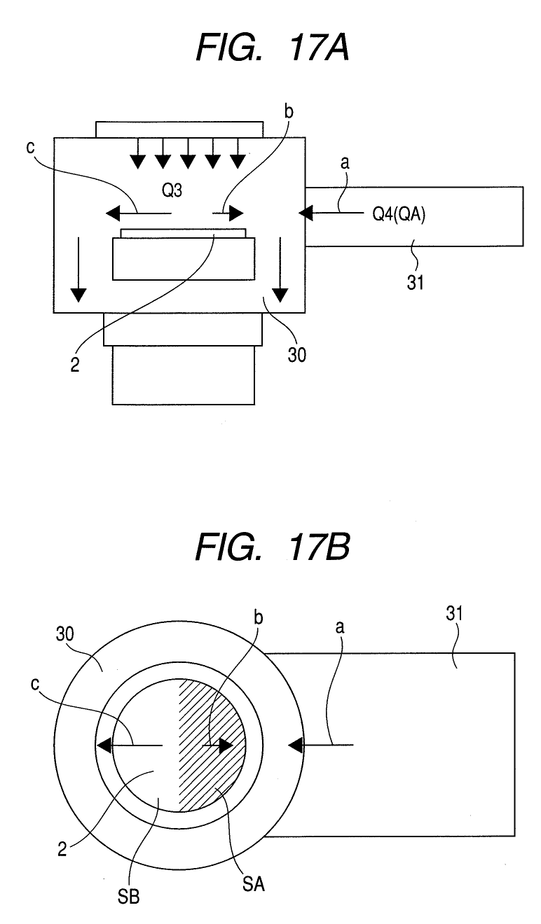

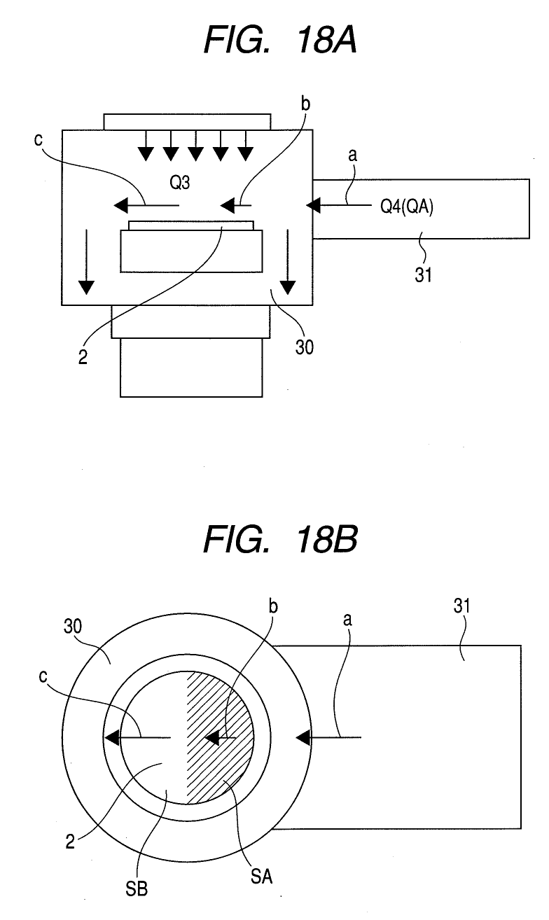

This gas flow will be simply described again using FIG. 17A and FIG. 17B, and FIG. 18A and FIG. 18B. FIGS. 17A and 17B are diagrams for simply explaining the gas flow in FIG. 10. FIGS. 18A and 18B are diagrams for simply explaining the gas flow in FIG. 16. FIG. 17A and FIG. 18A are schematic side views of the apparatus, and FIG. 17B and FIG. 18B are top views of the apparatus. Although the shape of the transport chamber 31 is very simplified and shown in the FIGS. 17A to 18B, the actual shape is as shown in FIG. 2, for example. The arrows in the FIGS. 17A to 18B indicate the direction of a gas flow. Especially, a gas flow (a) indicates the flow direction of gas flowing from the transport chamber into the processing chamber, a gas flow (b) indicates the average flow direction of an area SA (½ of one object to be processed) on the transport chamber side indicated by slant lines on the surface of the object to be processed (or on the placing surface of the sample placing electrode), and a gas flow (c) indicates the average flowing direction of an area SB (½ of one object to be processed) on the opposite side to the transport chamber.

In order to prevent foreign particles flowing in from the transport chamber from adhering to the object to be processed, it is desirable that the average flow direction (b) of gas in the area SA on the transport chamber side on the object to be processed points, as shown in FIGS. 17A and 17B, the transport chamber side in transporting the object to be processed and before and after it as indicated by the timing C in FIG. 4. In other words, in the above timing, as shown in FIGS. 18A and 18B, it is not desirable that on the surface of the wafer 2 to be processed, the average gas flow direction (b) in the area SA on the transport chamber side is opposite to the direction of the transport chamber. In order to produce such a gas flow, it is necessary that the flow rate QA of gas supplied to the transport chamber should be smaller than the flow rate Q3 of gas let flow in the processing chamber. Briefly, the following formula (5) should hold:

Q3÷2>QA (5)

Wherein Q3 is the total flow rate of gas supplied into the processing chamber and QA is the flow rate of gas flowing in the processing chamber from the transport chamber.

In the case where the exhaust velocity in the transport chamber is enough smaller than the exhaust velocity on the processing chamber side, the above formula may be replaced with the following formula. That is, as the case where the exhaust velocity of the transport chamber is small, cited is the case where while the turbo molecular pump 17 is installed on the processing chamber side as shown in FIG. 1, any turbo molecular pump is not connected to the transport chamber. In the case where the turbo molecular pump 17 is connected to the transport chamber as well, the flow rate of gas supplied to the transport chamber may be larger than the flow rate indicated by the formula (6), but it is more desirable to determine the flow rate by applying the following formula (6) thereto.

Q3÷2>Q4 (6)

Wherein Q3 is the total flow rate of gas supplied to the processing chamber and Q4 is the total flow rate of gas supplied to the transport chamber.

Even if the flow rate of gas let flow in the transport chamber satisfies the formula (6), the gas flowing in the processing chamber from the transport chamber must not be a flow like a jet. When the flow velocity of gas flowing in the processing chamber from the transport chamber is too high, the foreign particles flow in the processing chamber at a high speed to reduce the effect of controlling the transport of a foreign matter by the gas flow in the processing chamber. Therefore, the flow velocity of gas flowing in the processing chamber from the transport chamber should be several m/s or less.

In this case, when the flow rate of gas flowing in the transport chamber is f_{T} [ccm], the size of a transport passage connecting the processing chamber and the transport port is x[m] in width and z[m] in height, and the pressure in the transport chamber in the open state of the first gate valve and the second gate valve is P_{T}, the flow velocity V_{T} of gas can be expressed by the formula (7).

V_{T}≈f_{T}/(6×10²×P_{T}×x×z) (7)

For example, in the apparatus coping with 300 mm wafer, the width x of the transport port should be 0.3 m or more, and for example, it is 0.4 m. When the height z of the transport port is 0.02 m and the total flow rate Q4 of gas supplied to the transport chamber is 1000 ccm, the flow velocity of gas is about 7 m/s. In this case, the total flow rate Q4 of gas supplied to the transport chamber is decreased to 500 ccm or less, or the sectional area of the transport passage is enlarged, so that it is necessary to increase the width of the transport passage or the height of the transport passage. Actually, it is desirable to set the height of the transport passage to 1 cm or more.

According to the embodiment of the invention, as described above, in transporting the object to be processed while gas is let flow in the processing chamber and the transport chamber by the foreign matter control function by the gas flow, the average flowing direction of gas in the area at the transport chamber side on the object to be processed may point the transport chamber side. Thus, the number of foreign particles adhering to the object to be processed in transporting the object can be decreased, and the yield of the semiconductor device can be improved.

### Embodiment 2

Although the description of the embodiment 1 deals with a configuration example in which the first gate valve and the second gate valve are separate members, another configuration may be adopted, in which a single gate valve has functions of both first and second gate valves, in other words, a single gate valve installed in a transport passage and on the processing chamber side from a clearance gap 110 may have a function of controlling the communicating state between a plasma processing chamber and a transporting chamber in multistage such as the totally closing, partially opening, and fully opening.

Although the description of the embodiments of the invention deals with the example applied to the parallel plate UHF-ECR plasma etching device, needless to say, the semiconductor manufacturing apparatus of the invention is not limited to this, but it may be widely applied to a plasma processing apparatus of another system including an sample placing electrode in the plasma processing chamber.

Further, the invention may be widely applied to the other semiconductor manufacturing apparatus such as plasma CVD apparatus.

What is claimed is:

1. A method for transporting an object to be processed in a semiconductor manufacturing apparatus, the apparatus including a processing chamber for processing an object to be processed, processing chamber gas supply means for supplying processing gas and transport gas to the processing chamber, processing chamber evacuating means for decompressing the processing chamber, a vacuum transport chamber for transporting the object to be processed in the processing chamber, transport chamber gas supply means for supplying transport gas to the vacuum transport chamber, vacuum transport chamber evacuating means for decompressing the vacuum transport chamber, and a gate valve provided between the vacuum transport chamber and the processing chamber, wherein, in when transporting the object to be processed while supplying the transport gas to the processing chamber and the vacuum transport chamber, respectively, wherein the method comprising steps of:
controlling the flow rate of the transport gas supplied to the processing chamber by the processing chamber gas supply means in a state to be twice or more the flow rate of the transport gas supplied to the vacuum transport chamber by the transport chamber gas supply means, and
opening the gate valve to transport the object to be processed between the vacuum transport chamber and the processing chamber in the state.

2. The method for transporting an object to be processed in the semiconductor manufacturing apparatus according to claim 1, wherein
the gate valve is opened for transporting the object between the vacuum transport chamber and the processing chamber with the pressure in the processing chamber set to 5 to 50 Pa and with the pressure in the vacuum transport chamber set to positive pressure with a differential pressure of 10 Pa or less to the pressure in the processing chamber.

3. The method for transporting an object to be processed in the semiconductor manufacturing apparatus according to claim 1, wherein
the semiconductor manufacturing apparatus further includes a sample placing electrode disposed in the processing chamber, the gate valve is provided on the side of the sample placing electrode and also in a transport passage for an object to be processed, which connects the vacuum transport chamber with the processing chamber,
wherein the object to be processed is transported between the sample placing electrode and the vacuum transport chamber in a state with the average flow direction of the transport gas pointing the transport chamber side, on the placing surface of the sample placing electrode or in an area on the transport chamber side of the object to be processed on the placing surface.

4. A method for transporting an object to be processed in a semiconductor manufacturing apparatus, the apparatus including a processing chamber for processing an object to be processed, processing chamber gas supply means for supplying gas to the processing chamber, processing chamber evacuating means for decompressing the processing chamber, a vacuum transport chamber for transporting the object to be processed in the processing chamber, transport chamber gas supply means for supplying gas to the vacuum transport chamber, vacuum transport chamber evacuating means for decompressing the vacuum transport chamber, and a gate valve provided between the vacuum transport chamber and the processing chamber, wherein, in when transporting the object to be processed while the transport gas flows to the processing chamber and the vacuum transport chamber, respectively, wherein the method comprising steps of:
transporting the object to be processed between the processing chamber and the vacuum transport chamber while supplying the transport gas to each of chambers, respectively, wherein when transporting the object,
controlling the flow rate of gas supplied to the processing chamber to be twice or more the flow rate of gas supplied to the vacuum transport chamber, and
opening the gate valve for transporting the object to be processed between the vacuum transport chamber and the processing chamber, with the pressure in the processing chamber set to 5 to 50 Pa and with the pressure in the vacuum transport chamber set to the positive pressure with a differential pressure of 10 Pa or less to the pressure in the processing chamber.

5. The method for transporting an object to be processed in the semiconductor manufacturing apparatus according to claim 4,
wherein the gate valve includes a first gate valve provided in a transport passage for an object to be processed, which connects the vacuum transport chamber with the processing chamber to open and close the transport passage and a second gate valve installed on the processing chamber side from the first gate valve in the transport passage, wherein when opening the gate valve:
controlling the pressure in the processing chamber set to 5 to 50 Pa, and the pressure in the vacuum transport chamber set to the positive pressure with a differential pressure of 10 Pa or less to the pressure in the processing chamber,
opening the first gate valve in the controlled pressure, and subsequently the second gate valve to put the processing chamber and the vacuum transport chamber in the communicating state for transporting the object to be processed.

6. The method for transporting an object to be processed in the semiconductor manufacturing apparatus according to claim 5,
wherein the processing chamber includes an outer container and an inner container provided inside thereof to be replaceable,
a gas passage for releasing the gas not through the interior of the processing chamber is provided between the inner container and the outer container,
wherein the gas passage is communicated with the transport passage between the first gate valve and the second gate valve, wherein the method further comprising step of:
releasing the gas flowing in from the transport chamber through the gas passage in a state with the first gate valve opened and with the second gate valve closed.

7. The method for transporting an object to be processed in the semiconductor manufacturing apparatus according to claim 5,
wherein the semiconductor manufacturing apparatus includes: a butterfly valve disposed between the processing chamber and the processing chamber evacuating means; and an exhaust conductance adjusting valve connected to the transport chamber, wherein the method further comprising steps of:
adjusting the pressure of gas in the processing chamber by the opening and closing degree of the butterfly valve, and
adjusting the pressure of gas in the transport chamber by the exhaust conductance adjusting valve.

8. A method for transporting an object to be processed in a semiconductor manufacturing apparatus, the apparatus including a processing chamber for processing an object to be processed, processing chamber gas supply means for supplying gas to the processing chamber, processing chamber evacuating means for decompressing the processing chamber, a vacuum transport chamber for transporting the object to be processed in the processing chamber, transport chamber gas supply means for supplying gas to the vacuum transport chamber, vacuum transport chamber evacuating means for decompressing the vacuum transport chamber, and a gate valve provided between the vacuum transport chamber and the processing chamber,
wherein the semiconductor manufacturing apparatus further includes a sample placing electrode disposed in the processing chamber, the gate valve is provided on the side of the sample placing electrode and also in a transport passage for the object to be processed, which connects the vacuum transport chamber with the processing chamber, wherein the method comprising step of:
transporting the object to be processed between the processing chamber and the vacuum transport chamber while supplying the transport gas to both chambers, respectively,
wherein when transporting the object, supplying the transport gas is controlled to hold the following formula (5) in a placing surface of the sample placing electrode or an area on the transport chamber side of the object to be processed on the placing surface, wherein Q3 is the total flow rate of gas supplied into the processing chamber and QA is the flow rate of gas flowing in the processing chamber from the transport chamber.
Q3÷2>QA (5)

9. The method for transporting an object to be processed in the semiconductor manufacturing apparatus according to claim 8, wherein when transporting the object, supplying the transport gas is controlled to hold the following formula (6), wherein Q4 is the total flow rate of gas supplied to the transport chamber.
Q3÷2>Q4 (6)

10. The method for transporting an object to be processed in a semiconductor manufacturing apparatus according to claim 8, wherein the semiconductor manufacturing apparatus further includes a control computer, and
the control computer executes the respective program elements of a plasma processing chamber pressure control unit, a vacuum transport chamber gas supply quantity control unit, a plasma processing chamber pressure control unit, a vacuum transport pressure control unit, a first gate valve control unit, and a second gate valve control unit, wherein the method comprising steps of:
controlling the flow rate of the transport gas supplied to the processing chamber by the processing chamber gas supply means and the flow rate of the transport gas supplied to the vacuum transport chamber by the transport chamber gas supply means,
opening the gate valve in the state of the flow rate of the transport gas supplied to the processing chamber is controlled to be twice or more the flow rate of the transport gas supplied to the vacuum transport chamber, and
transporting the object to be processed between the vacuum transport chamber and the processing chamber.
